(19) United States
(12) Patent Application Publication
(10) Pub. No.: US 2025/0344396 A1
(43) Pub. Date: Nov. 6, 2025

(54) SEMICONDUCTOR DEVICE

(71) Applicant: Winbond Electronics Corp., Taichung City (TW)

(72) Inventor: Riichiro Shirota, Taichung City (TW)

(73) Assignee: Winbond Electronics Corp., Taichung City (TW)

(21) Appl. No.: 19/071,767

(22) Filed: Mar. 6, 2025

(30) Foreign Application Priority Data
May 1, 2024 (JP) 2024-074328
May 13, 2024 (JP) 2024-077743
Aug. 20, 2024 (JP) 2024-139175

(51) Int. Cl. H10B 43/35; H10B 43/40

(52) U.S. Cl. CPC H10B 43/35; H10B 43/40

(57) ABSTRACT

A semiconductor device formed by integrating a NOR memory cell array and a NAND memory cell array is provided. A flash memory includes a memory cell array, formed by integrating the NOR memory cell array and the NAND memory cell array; a word line, connected to each memory cell; and a bit line, commonly connected to the NOR memory cell array and the NAND memory cell array. The NOR memory cell array includes multiple memory cells connected in series between a bit line side select transistor and a source line side select transistor. Each of the memory cells includes a memory cell transistor and a sidewall transistor connected in parallel. The NAND memory cell array includes multiple memory cells connected in series between a bit line side select transistor and a source line side select transistor.

### CROSS-REFERENCE TO RELATED APPLICATION

This application claims the priority benefit of Japan Application No. 2024-074328, filed on May 1, 2024, Japan Application No. 2024-077743, filed on May 13, 2024, and Japan Application No. 2024-139175, filed on Aug. 20, 2024. The entirety of each of the above-mentioned patent applications is hereby incorporated by reference herein and made a part of this specification.

### BACKGROUND

### Technical Field

The disclosure relates to a semiconductor device, and more particularly to a semiconductor device including a memory cell array formed by integrating a NOR memory cell and a NAND memory cell.

### Description of Related Art

The Not OR (NOR) flash memory may perform random access and high-speed reading, and the Not AND (NAND) flash memory may implement a highly integrated memory cell array and program a large amount of data at high speed, but takes longer to read than the NOR flash memory.

As a device integrating memory cell arrays with different cell structures, Japanese Patent No. 7170117 discloses a nonvolatile memory including a memory cell array formed with a NOR array and a resistance variable array.

If the NOR flash memory and the NAND flash memory may be integrated on one chip, a flash memory having the advantages of each may be provided. However, the NOR flash memory has an array structure in which a memory cell is connected between a bit line and a source line, and the NAND flash memory has an array structure in which multiple memory cells are connected in series between a bit line and a source line. Therefore, it is difficult to integrate different array structures on one chip. If the same is to be implemented, the manufacturing process may be very complicated.

### SUMMARY

The disclosure provides a semiconductor device integrating a NOR memory cell array and a NAND memory cell array.

The semiconductor device of the disclosure includes a memory cell array formed by integrating a NOR memory cell array and a NAND memory cell array. The memory cell array has an active region, extending along a bit line direction within a substrate; a trench, adjacent to the active region; a charge storage layer, formed in the active region corresponding to each memory cell and including a nitride layer sandwiched between insulating layers; a first conductive layer, formed on the charge storage layer corresponding to each memory cell; and a second conductive layer, extending along a word line direction and electrically connected to the first conductive layer.

In an embodiment, the semiconductor device further includes a bit line commonly connected to the NOR memory cell array and the NAND memory cell array. In an embodiment, the semiconductor device further includes a first bit line connected to the NOR memory cell array and a second bit line connected to the NAND memory cell array. The first bit line and the second bit line are separated. In an embodiment, the first bit line is connected to a first sense circuit, and the second bit line is connected to a second sense circuit. The first sense circuit senses data of a selected memory cell of the NOR memory cell array, and the second sense circuit senses data of a selected memory cell of the NAND memory cell array. In an embodiment, the first conductive layer and the second conductive layer form a word line. In an embodiment, the NOR memory cell array further includes a sidewall insulator. The sidewall insulator is formed within the trench and is formed on a sidewall of the active region, and the second conductive layer contacts the sidewall insulator within the trench. In an embodiment, a NOR memory cell includes a memory cell transistor formed on a surface side of the active region and a sidewall transistor including the sidewall insulator. The memory cell transistor and the sidewall transistor are connected in parallel. In an embodiment, the trench is aligned with sidewalls of the active region, the first conductive layer, and the charge storage layer. In an embodiment, the charge storage layer includes an oxide-nitride-oxide (ONO) structure, or a stacked structure of multiple insulating films other than oxide is included between a silicon substrate and a nitride layer, or a stacked structure of multiple insulating films other than oxide is included between the nitride and the first conductive layer. In an embodiment, the NOR memory cell array includes multiple memory cells connected in series between a bit line side select transistor and a source line side select transistor, and the NAND memory cell array includes multiple memory cells connected in series between a bit line side select transistor and a source line side select transistor.

The semiconductor device of the disclosure includes a memory cell array, formed by integrating a NOR memory cell array and a NAND memory cell array; a word line, connected to each memory cell; and a bit line, commonly connected to the NOR memory cell array and the NAND memory cell array. The NOR memory cell array includes multiple memory cells connected in series between a bit line side select transistor and a source line side select transistor, and a memory cell includes a memory cell transistor and a sidewall transistor connected in parallel. The NAND memory cell array includes multiple memory cells connected in series between a bit line side select transistor and a source line side select transistor.

In an embodiment, a threshold of the sidewall transistor is set to be higher than a voltage of a selected word line and lower than a voltage of a non-selected word line. In an embodiment, the semiconductor device includes a control unit for controlling reading and writing of a memory cell array. The control unit performs reading and writing of the NOR memory cell array in units of pages and in units of memory cells, and performs reading and writing of the NAND memory cell array in units of pages.

According to the disclosure, the memory cell array includes an active region, formed within a substrate in a manner extending along a bit line direction; a trench, adjacent to the active region; a charge storage layer, formed in the active region for each memory cell and including a nitride layer sandwiched between insulating layers; a first conductive layer, formed on the charge storage layer for each memory cell; and a second conductive layer, extending along a word line direction and electrically connected to the first conductive layer. Therefore, the NOR memory cell array and the NAND memory cell array may be easily integrated in the memory cell array using an interchangeable process.

### BRIEF DESCRIPTION OF THE DRAWINGS

FIG. 1A is a block diagram of an overall structure of a flash memory according to an embodiment of the disclosure.

FIG. 1B is a block diagram of another structural example of a flash memory according to an embodiment of the disclosure.

FIG. 2A is an equivalent circuit diagram of a NOR memory cell array and a NAND memory cell array formed by a memory cell array of the embodiment.

FIG. 2B is an equivalent circuit diagram of another structural example of a memory cell array of the embodiment.

FIG. 3 is a plan diagram of a NOR memory cell array and a NAND memory cell array formed by a memory cell array of the embodiment.

FIG. 4A is a plan diagram of a part of a NAND memory cell array including an active region and a trench, and FIG. 4B is a cross-sectional diagram taken along a line A1-A1 of FIG. 4A.

FIG. 5 is a cross-sectional diagram of the NAND memory cell array taken along a line A2-A2 of FIG. 3.

FIG. 6A is a cross-sectional diagram in which the NOR memory cell is formed taken along a line B1-B1 of FIG. 3, and FIG. 6B is a cross-sectional diagram in which the NOR memory cell is not formed taken along a line B2-B2 of FIG. 3.

FIG. 7A is an equivalent circuit diagram of a NOR memory cell of the embodiment, and

FIG. 7B is a cross-sectional diagram for explaining two transistors formed in the NOR memory cell.

FIG. 8 is a threshold distribution diagram of a memory cell.

FIG. 9 is a diagram of a part of a NOR memory cell array during a program operation.

FIG. 10A to FIG. 10C and FIG. 11A to FIG. 11D are diagrams of a manufacturing process of a NAND memory cell array of the embodiment.

FIG. 12A is a plan diagram of a substrate when a first control gate, a charge storage layer, and the substrate are etched through a mask pattern, and FIG. 12B is a plan diagram of the substrate when heights of the first control gate and a trench insulator are substantially the same.

FIG. 13A to FIG. 13C and FIG. 14A to FIG. 14D are diagrams of a manufacturing process of a NOR memory cell array of the embodiment.

FIG. 15A is a plan diagram of a substrate after a mask pattern M1 is removed, and FIG. 15B is a plan diagram of the substrate after a mask pattern M2 is formed.

FIG. 16A to FIG. 16D are diagrams of a manufacturing process of a cell array region and a peripheral region of a flash memory of the embodiment.

FIG. 17A, FIG. 17B, FIG. 19A, and FIG. 19B are diagrams of another manufacturing process of a cell array region and a peripheral region of a flash memory of the embodiment.

FIG. 18A to FIG. 18C are diagrams of a manufacturing process of a cell array region and a peripheral region of a flash memory of the embodiment.

### DESCRIPTION OF THE EMBODIMENTS

A semiconductor device of the disclosure is a memory cell array formed by integrating a NOR memory cell array and a NAND memory cell array on the same substrate, so that large memory capacity and high-speed reading may be implemented. The NOR memory cell array and the NAND memory cell array have similar structures including common elements and thus may be manufactured using compatible process. Furthermore, it should be noted that the drawings include parts that are exaggerated to facilitate understanding of the disclosure and do not necessarily represent actual scales of products.

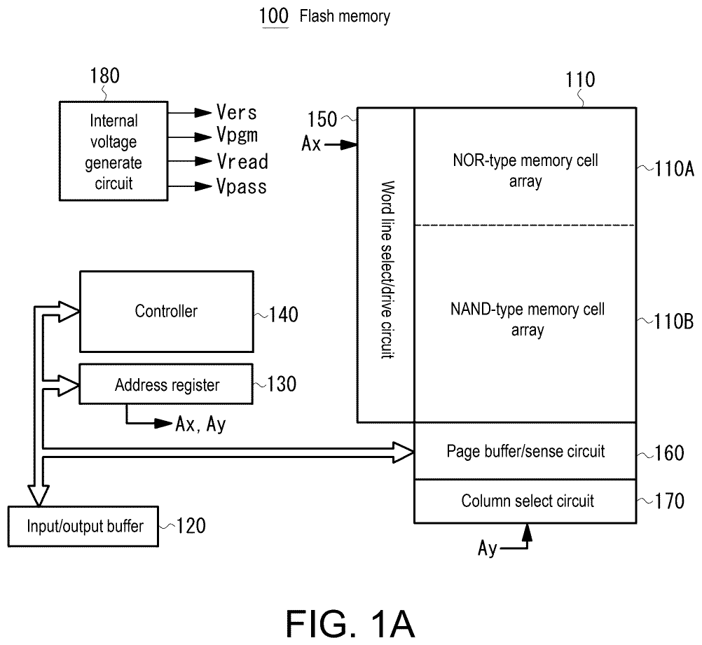

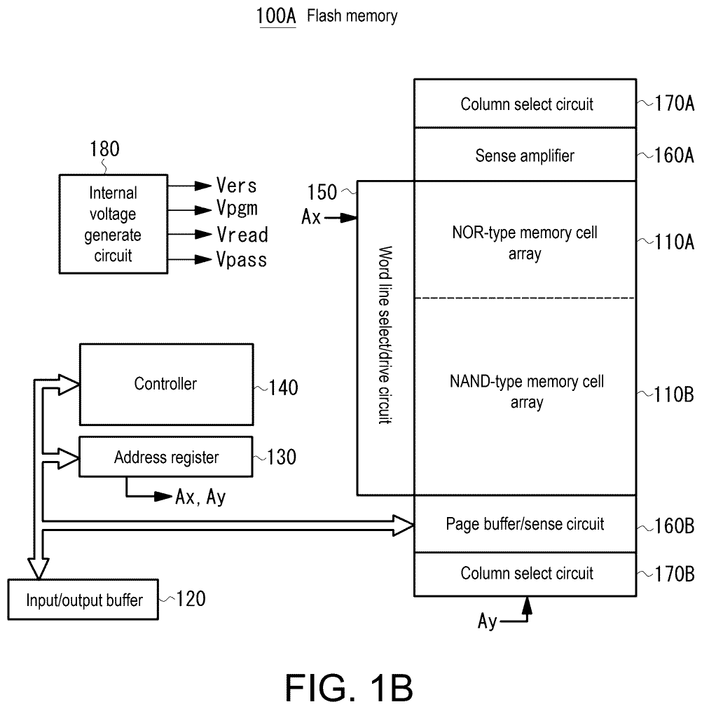

FIG. 1A is a schematic block diagram of an overall structure of a flash memory according to an embodiment of the disclosure. As shown in FIG. 1A, a flash memory 100 includes a memory cell array 110 formed with a NOR memory cell array 110A (hereinafter referred to as a NOR array) and a NAND memory cell array 110B (hereinafter referred to as a NAND array); an input/output buffer 120 connected to an external input/output (I/O) terminal; an address register 130 receiving address data from the input/output buffer 120; a controller 140 controlling each component based on command data or an external control signal from the input/output buffer 120; a word line select/drive circuit 150 selecting a block or a word line of the memory cell array 110 based on row address information Ax from the address register 130; a page buffer/sense circuit 160 sensing data read from the memory cell array 110 or retaining data programmed into the memory cell array 110; a column select circuit 170 selecting a column (bit line) of the page buffer/sense circuit 160 based on column address information Ay from the address register 130; and an internal voltage generate circuit 180 generating various voltages (a program voltage Vpgm, a read voltage Vread, an erase voltage Vers, a programming or reading pass voltage Vpass, etc.) required for reading, programming, erasing etc.

In the embodiment shown in FIG. 1A, the page buffer/sense circuit 160 and the column select circuit 170 are commonly disposed in the NOR array 110A and the NAND array 110B. Alternatively, separate sense circuits may also be disposed in the NOR array 110A and the NAND array 110B. For example, as shown in FIG. 1B, in a flash memory 100A of the embodiment, a sense amplifier (SA) 160A and a column select circuit 170A are disposed in the NOR array 110A, and a page buffer/sense circuit 160B and a column select circuit 170B are disposed in the NAND array 110B. The sense amplifier 160A and the page buffer/sense circuit 160B operate independently. The sense amplifier 160A may read or write data from a selected memory cell of the NOR array 110A. The page buffer/sense circuit 160B may read or write data from a selected page of the NAND array 110B. Through separating the sense amplifier 160A and the page buffer/sense circuit 160B, the read speed of the NOR array may be increased.

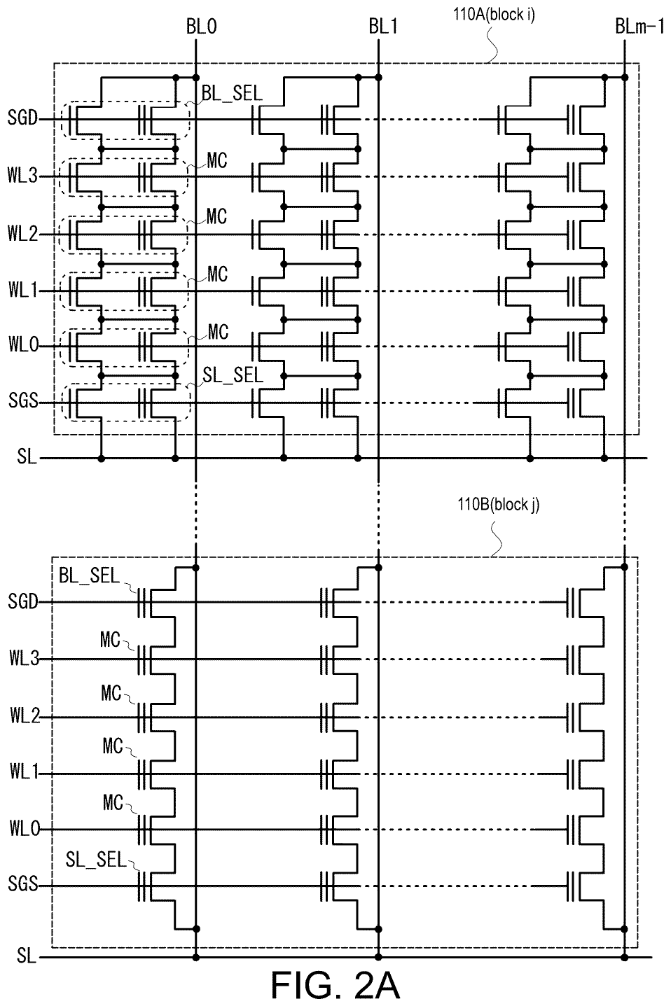

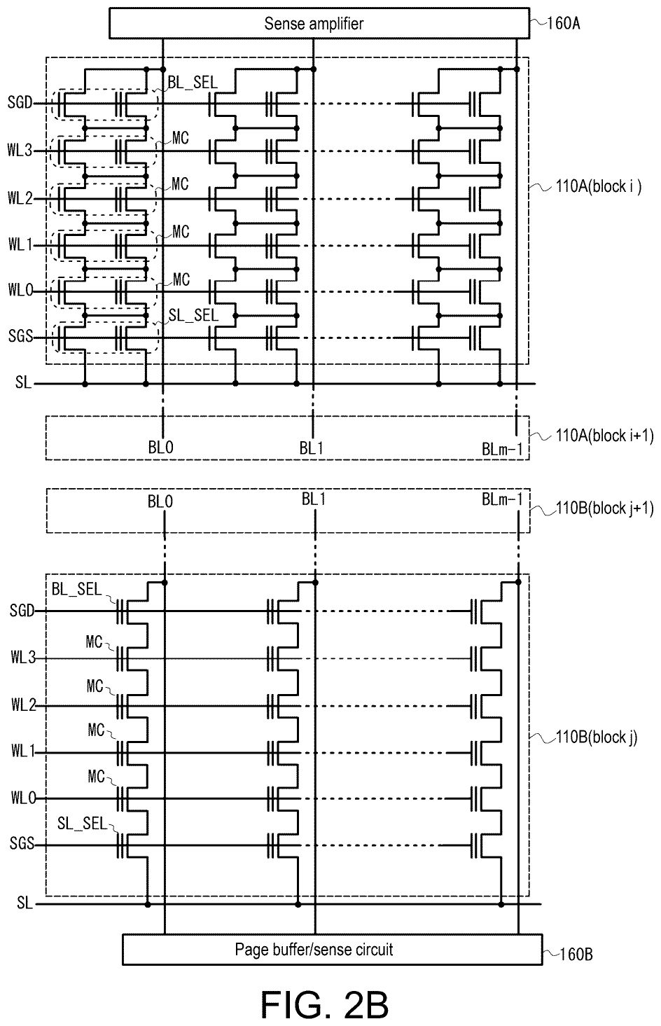

The memory cell array 110 includes the NOR array 110A and the NAND array 110B integrated on a substrate. The NOR array 110A includes, for example, multiple blocks disposed in a column direction, and the NAND array 110B includes, for example, multiple blocks disposed in a column direction. FIG. 2A and FIG. 2B show an equivalent circuit of a block of the NOR array 110A and an equivalent circuit of a block of the NAND array 110B. A bit line BL0 to a bit line BLm−1 are commonly used by multiple blocks in the column direction of the NOR array 110A and multiple blocks in the column direction of the NAND array 110B. Here, in the memory cell array 110, a memory cell MC connected to a word line WL may be referred to as a page, and memory cells within multiple pages sandwiched between a bit line side select transistor BL_SEL and a source line side select transistor SL_SEL may be referred to as a block, which are the same as those of a general NAND flash memory.

In the embodiment shown in FIG. 2A, the bit line BL0 to the bit line BLm−1 are commonly connected to the NOR array 110A and the NAND array 110B. The bit line BL0 to the bit line BLm−1 may also be respectively connected to the NOR array 110A and the NAND array 110B to be separated. For example, as shown in FIG. 2B, the bit line BL0 to the bit line BLm−1 are connected to a block i and a block i+1 of the NOR array 110A, and each of the bit lines is connected to the sense amplifier 160A. On the other hand, the bit line BL0 to the bit line BLm−1 are connected to a block j and a block j+1 of the NAND array 110B, and each of the bit lines is connected to the page buffer/sense circuit 160B. In this way, through separating the bit lines of the NOR array 110A and the NAND array 110B, load on the bit lines may be reduced, and as a result, high-speed reading or writing may be implemented. In addition, the sense amplifier 160A may be prepared in a number corresponding to the number of the bit line BL0 to the bit line BLm−1 (the number of one page) or may be prepared in a number corresponding to the number of one or more bit lines, so that the bit lines selected by a switch circuit are connected to the sense amplifier 160A.

Multiple NAND strings are formed in one block of the NAND array 110B. One NAND string includes the bit line side select transistor BL_SEL, the source line side select transistor SL_SEL, and multiple memory cells MC connected in series therebetween. The memory cell MC may store binary data and may also store multi-valued data.

The bit line side select transistor BL_SEL is connected to a corresponding bit line among the bit line BL0 to the bit line BLm−1, and a gate is connected to a select gate line SGD. The source line side select transistor SL_SEL is connected to a common source line SL, and a gate is connected to a select gate line SGS. For example, four memory cells MC are shown here, and respective gates of the memory cells MC are connected to word lines WL0 to WL3.

The word line WL, the select gate line SGD, and the select gate line SGS of each block of the NAND array 110B are connected to the word line select/drive circuit 150. The bit line BL0 to the bit line BLm−1 are commonly connected to each block, and one terminal thereof is connected to the page buffer/sense circuit 160. In addition, as shown in FIG. 1B and FIG. 2B, in the case where the NOR array 110A and the NAND array 110B are respectively provided with the sense amplifier 160A and the page buffer/sense circuit 160B, the bit line BL0 to the bit line BLm−1 of the NOR array 110A are connected to the sense amplifier 160A, and the bit line BL0 to the bit line BLm−1 of the NAND array 110B are connected to the page buffer/sense circuit 160B.

On the other hand, in the NOR array 110A, multiple memory cells MC are connected in series between the bit line side select transistor BL_SEL connected to the select gate line SGD and the source line side select transistor SL_SEL connected to the select gate line SGS. The memory cell MC includes a memory cell transistor CELL_TR and a sidewall transistor SW_TR connected in parallel. Each memory cell MC is connected to the corresponding word line WL0 to word line WL3 in a row direction, the bit line side select transistor BL_SEL is connected to the corresponding bit line among the bit line BL0 to the bit line BLm−1, and the source line side select transistor SL_SEL is connected to the common source line SL. For example, four memory cells MC are shown here.

The word line select/drive circuit 150 selects a block of the NOR array 110A or a block of the NAND array 110B based on the row address information Ax, thereby driving the select gate line SGD/SGS and the word line WL0 to the word line WL3 within the selected block. The page buffer/sense circuit 160 senses data read from a selected page of the NOR array 110A or the NAND array 110B or writes data to be programmed into the selected page of the NOR array 110A or the NAND array 110B. In addition, as shown in FIG. 1B and FIG. 2B, in the case where the sense amplifier 160A and the page buffer/sense circuit 160B are respectively disposed in the NOR array 110A and the NAND array 110B, the sense amplifier 160A senses data read from the selected memory cell or the selected page of the NOR array 110A or retains data correspondingly programmed therein, and the page buffer/sense circuit 160B senses data read from the selected page of the NAND array 110B or retains data correspondingly programmed therein.

The controller 140 is composed of a microcontroller or a state machine including a read only memory (ROM)/random access memory (RAM) and controls a read operation, a program operation, an erase operation, etc. of the NOR array 110A and the NAND array 110B. In the NAND array 110B, reading in units of pages, programming in units of pages, and erasing in units of blocks may be performed. On the other hand, in the NOR array 110A, in addition to reading in units of pages, programming in units of pages, and erasing in units of blocks, reading in units of memory cells, programming in units of memory cells, and erasing in units of pages may also be performed.

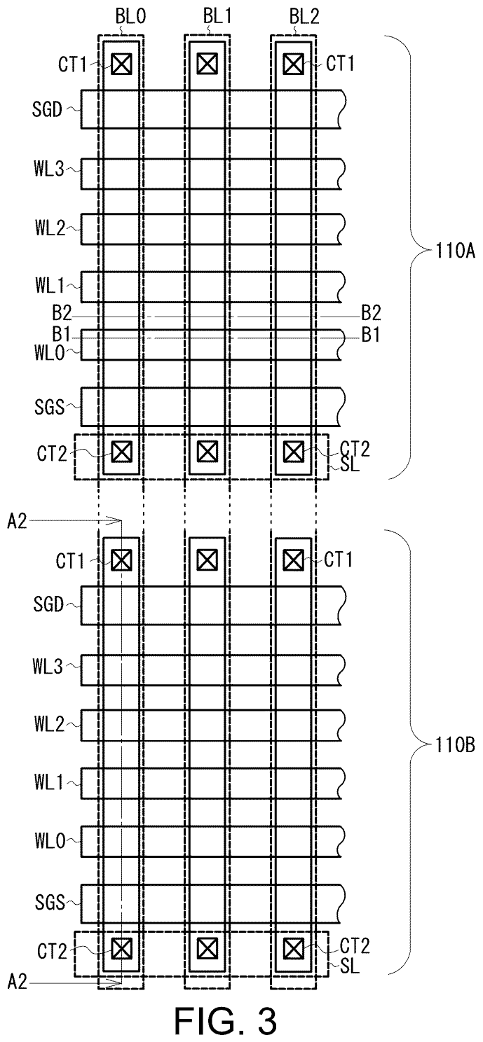

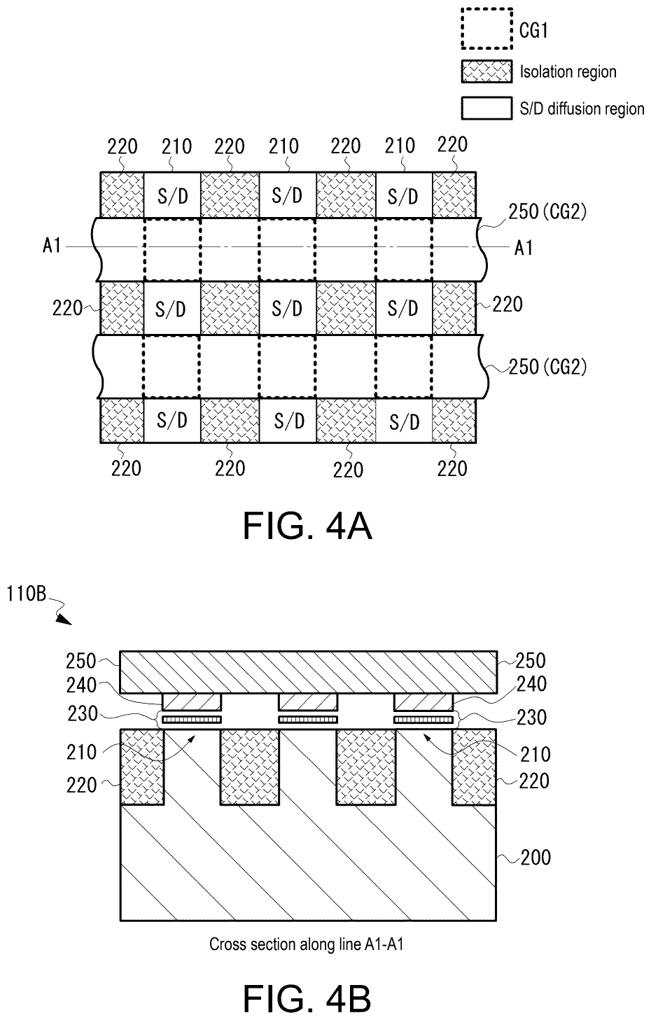

Next, the NAND array 110B will be described in detail. FIG. 3 is a plan diagram of the NOR array 110A and the NAND array 110B corresponding to the equivalent circuit of FIG. 2. FIG. 4A is a plan diagram of an active region, a trench, a first control gate, and a second control gate of a NAND array, and FIG. 4B is a cross-sectional diagram taken along a line A1-A1 of FIG. 4A.

Active regions 210 extending along a bit line direction are formed on a P-type silicon substrate or P well 200, and each of the active regions 210 in the bit line direction is isolated by a trench 220 extending along the bit line direction. The active region 210 provides a channel region or an N-type source/drain (S/D) diffusion region for a memory cell. Multiple insulating layer stacks with SiN layers interposed therebetween are formed in the active region 210 to form a charge storage layer 230. The charge storage layer 230 is patterned in the active region 210 corresponding to each memory cell.

The charge storage layer 230 may, for example, have an oxide-nitride-oxide (ONO) structure. Alternatively, various insulating films may be stacked between a silicon substrate and a nitride layer instead of a single oxide layer. In addition, various insulating films may be stacked between a nitride and a gate instead of a single oxide layer.

A patterned first control gate (CG1) 240 is formed on the charge storage layer 230 to be aligned with the charge storage layer 230. The first control gate 240 includes, for example, doped conductive polysilicon or may be formed by stacking multiple low resistance materials, such as TaN or other metal layers. A second control gate (CG2) 250 patterned to extend along a word line direction (the row direction) is formed on the first control gate 240. The second control gate 250 is electrically connected to the first control gate 240. The second control gate 250 is ideally low in resistance and may include, for example, a metal material such as Al or Cu. In addition, the first control gate 240 may include the same material as or a different material from the second control gate 250.

Although not shown here, similarly for the bit line side select transistor and the source line side select transistor, the second control gate 250 and the first control gate 240 together form an SGD gate line and an SGS gate line respectively, and the second control gate 250 is electrically connected to the first control gate 240 of the bit line side select transistor and the source line side select transistor respectively.

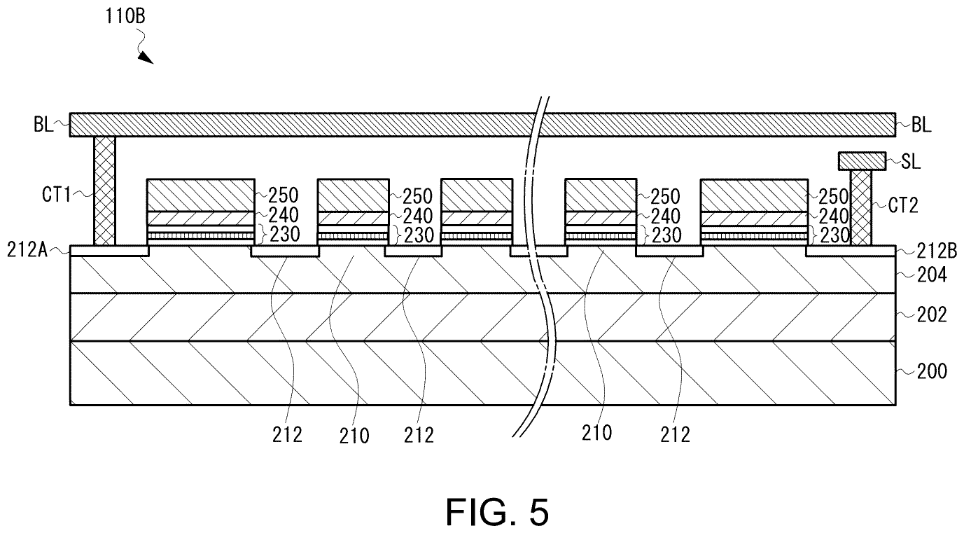

FIG. 5 is a cross-sectional diagram of the NAND array 110B taken along a line A2-A2 of FIG. 3, that is, a cross section in the bit line direction. As shown in FIG. 5, an N-well 202 is formed on the P-type silicon substrate 200, and a P-well 204 is formed within the N-well 202. The P-well 204 provides the active region 210, thereby providing an N-type diffusion region 212 for a source/drain of the memory cell, the bit line side select transistor, and the source line side select transistor. The charge storage layer 230 is formed on the P-well 204, and the first control gate 240 and the second control gate 250 are formed on the charge storage layer 230. A diffusion region 212A of the bit line side select transistor is electrically connected to the bit line BL via a contactor CT1, and a diffusion region 212B of the source line side select transistor is electrically connected to the source line SL via a contactor CT2.

In an embodiment, the charge storage layer has, for example, an oxide-nitride-oxide (ONO) structure. The ONO structure provides a silicon-oxide-nitride-oxide-silicon (SONOS) structure formed between a silicon substrate (or a silicon well) and the first control gate 240 containing polysilicon. During the program operation, the charge storage layer 230 stores charges Fowler-Nordheim (FN) tunneled through the oxide layer from the channel region on an inner surface of the nitride layer. During the erase operation, the charges stored in the charge storage layer FN tunnel through the oxide layer to be released to the channel region.

In the embodiment, the film thickness of the nitride layer (SiN layer) of the charge storage layer 230 is less than that of a floating gate of a floating gate (FG) structure, and the nitride layer is an insulating film. Therefore, compared with the FG structure, capacitive coupling between adjacent memory cells may be reduced, and as a result, the threshold distribution of the memory cells may be narrowed. Furthermore, in the case where the nitride layer of the charge storage layer 230 is continuously formed along the word line direction (not separated corresponding to each memory cell), if electrons retained in the nitride layer are attracted by electron holes and move or the electron holes are attracted by the electrons and move, there will be issues such as changes in the threshold of the memory cells. However, through separating the charge storage layer according to each memory cell as in the embodiment, the issue may be eliminated.

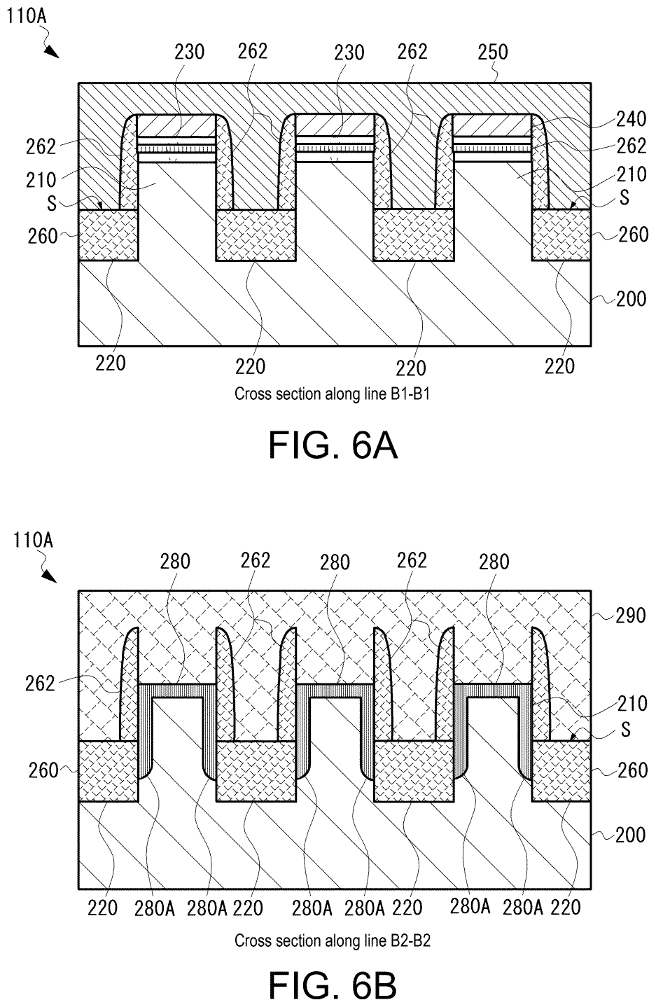

Next, the NOR array 110A will be described in detail. FIG. 6A is a cross-sectional diagram of a region where a memory cell of the NOR array 110A is formed taken along a line B1-B1 of FIG. 3. The NOR array 110A and the NAND array 110B are formed on the same substrate 200. Similar to the NAND array 110B, the NOR array 110A includes the active regions 210 extending along the bit line direction and the trench 220 isolating the active regions 210 formed on the substrate 200. In the active region 210, similar to the NAND array 110B, the patterned charge storage layer 230 is formed for each memory cell, and the patterned first control gate (CG1) 240 is formed above the charge storage layer 230 corresponding to each memory cell.

Here, in the case of the NOR array 110A, a trench insulator 260 is filled into the trench 220, so that an outermost surface S is lower than an outermost surface of the active region 210. In addition, a sidewall insulator 262 is formed to cover sidewalls of the first control gate 240 and the charge storage layer 230, and the bottom of the sidewall insulator 262 is connected to the trench insulator 260.

An outermost surface of the first control gate 240 is exposed through the sidewall insulator 262, and the second control gate 250 extending along the word line direction is formed on the first control gate 240. The second control gate 250 is electrically connected to the first control gate 240 directly below. The second control gate 250 and the first control gate 240 together form each of the word line WL0 to the word line WL3. The first control gate 240 and the second control gate 250 of the NOR array 110A are formed similarly to the NAND array 110B.

Although not shown here, similarly for the bit line side select transistor and the source line side select transistor, the second control gate 250 and the first control gate 240 together form the SGD gate line and the SGS gate line respectively, and the second control gate 250 is electrically connected to the first control gate 240 of the bit line side select transistor and the source line side select transistor respectively.

FIG. 6B is a cross-sectional diagram of a region where a memory cell is not formed in the NOR array 110A taken along a line B2-B2 of FIG. 3. An N-type diffusion region 280 of a memory cell is formed on a surface of the active region 210 adjacent to the channel region of the memory cell, that is, the surface of the active region 210 exposed by the word line. Furthermore, an N-type diffusion region 280A is formed at a certain depth on a side surface opposite to the active region 210, and the diffusion region 280A is connected to the diffusion region 280 on the surface.

Different from the region of the memory cell, the charge storage layer 230 and the first control gate 240 are not formed in the active region 210, and the sidewall insulator 262 protrudes from the surface of the active region 210. In addition, the second control gate 250 is not formed, and instead, an interlayer insulating film 290 is formed to cover the trench insulator 260, the sidewall insulator 262, and the active region 210.

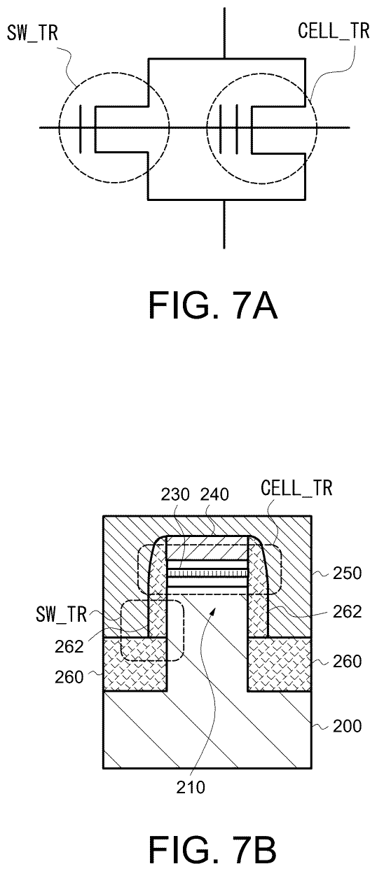

FIG. 7A is an equivalent circuit diagram of a NOR memory cell, and FIG. 7B is a cross-sectional diagram of the NOR memory cell. The memory cell transistor CELL_TR and the sidewall transistor SW_TR connected in parallel are formed in the NOR memory cell. The memory cell transistor CELL_TR includes a channel region of the outermost surface of the active region 210, the charge storage layer 230 and the first control gate 240 on the active region 210, and the N-type diffusion region 280 serving as a source/drain. On the other hand, the sidewall transistor SW_TR includes a channel region of a side surface of the active region 210, the sidewall insulator 262 serving as a gate insulating film, and the N-type diffusion region 280A serving as a source/drain. A threshold of the sidewall transistor SW_TR is adjusted through the film thickness of the sidewall insulator 262 or the concentration of boron of the channel region.

Similar to the NAND array 110B, in the NOR array 110A, in an embodiment, the charge storage layer 230 also has an oxide-nitride-oxide (ONO) structure, and the ONO structure also provides a SONOS structure formed between the silicon substrate (or silicon well) 200 and the first control gate 240 containing polysilicon. During the program operation, the charge storage layer 230 stores charges FN tunneled through the oxide layer from the channel region on an interface of the nitride layer. During the erase operation, the charges stored in the charge storage layer FN tunnel through the oxide layer to be released to the channel region.

In the embodiment, the NOR array 110A has a structure in which multiple memory cells are connected in series between the bit line side select transistor and the source line side select transistor, and thus has the same structure as the NAND array 110B. Therefore, in the case where the NOR array 110A and the NAND array 110B are formed on the same substrate, the manufacturing process may be simplified through a compatible manufacturing process.

Next, the operation of the flash memory 100 of the embodiment will be described. During the read operation of the NAND array 110B, a certain voltage (for example, 0 V) is applied to a selected word line, a read pass voltage (for example, 4.5 V) is applied to a non-selected word line, an H-level voltage (for example, 4.5 V) is applied to the select gate line SGD/SGS, and 0 V is applied to the source line SL. During the program operation, the high-voltage program voltage Vpgm (for example, 15 V to 20 V) is applied to the selected word line, a program pass voltage (for example, 10 V) is applied to the non-selected word line, the H-level voltage is applied to the select gate line SGD, and an L-level voltage is applied to the select gate line SGS. During the erase operation, 0 V is applied to the selected word line within the selected block, and the L-level voltage is applied to the select gate line SGD/select gate line SGS. The operations are the same as those of the general NAND flash memory.

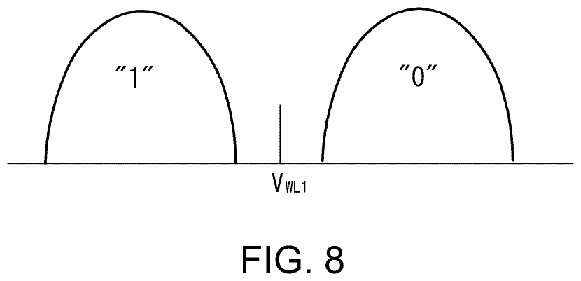

Next, the read operation of the NOR array 110A will be described. FIG. 8 shows a threshold Vt distribution of the memory cell transistor CELL_TR when the NOR array 110A stores one bit in each memory cell. V_{WL1} is a voltage applied to the word line WL of the selected memory cell during reading. The threshold Vt distribution of the sidewall transistor SW_TR must be higher than the voltage V_{WL1} of the selected word line.

The threshold Vt of a cell “1” is set to be lower than V_{WL1}. In the case where the threshold Vt of the memory cell transistor CELL_TR is lower than V_{WL1}, the selected memory cell transistor CELL_TR is in a conducted state and the sidewall transistor SW_TR is in a disconnected state. The threshold Vt of a cell “0” is set to be higher than V_{WL1}. In the case where the threshold Vt of the memory cell transistor CELL_TR is higher than V_{WL1}, the selected memory cell transistor CELL_TR is in a disconnected state, and the sidewall transistor SW_TR is in a disconnected state.

Table 1 shows a bias voltage of each component during the read operation. A cell of a page within the selected block may be simultaneously read. In order to correctly read the selected cell, a voltage V_{WL2} is applied to the non-selected word line. Here, V_{WL2} is set to be higher than the threshold Vt of the sidewall transistor SW_TR. Therefore, all the sidewall transistors SW_TR connected to the non-selected word lines are in a conducted state, that is, regardless of the threshold Vt of the memory cell transistor CELL_TR, all the non-selected memory cells are in a conducted state, and the sidewall transistor SW_TR of the selected memory cell is in a disconnected state, so that data of the selected memory cell transistor CELL_TR may be correctly read. During the read operation, a voltage higher than the thresholds Vt of the source line side select transistor SL_SEL and the bit line side select transistor BL_SEL is applied to an SGS gate and an SGD gate, so that the select transistors are in a conducted state.

TABLE 1
Read

| | Bias voltage | |
|---|---|---|
| V_{BL} | 0.5~1.5 | V |
| V_{SL} | 0 | V |
| V_{P-WELL} | 0 | V |
| Selected block | | |
| V_{WL} (selected WL) | V_{WL1} = 0~2 V | |
| V_{WL} (non-selected WL) | V_{WL2} = 1~3 V > V_{WL1} | |
| V_{SGS} | 1~3 | V |
| V_{SGD} | 1~3 | V |
| Non-selected block | | |
| V_{WL} | 0 | V |
| V_{SGS} | 0 | V |
| V_{SGD} | 0 | V |

For example, in FIG. 2A, when the data of the memory cell MC connected to the word line WL1 is read, the sidewall transistor SW_TR connected to the word line WL1 is in a disconnected state, and the sidewall transistors SW_TR connected to the non-selected word line WL0, the non-selected word line WL2, and the non-selected word line WL3 are all in a conducted state. According to the data “0” or “1” stored in the memory cell transistor CELL_TR connected to the word line WL1, current flows from the bit line BL to the source line SL and is sensed by the page buffer/sense circuit 160.

During reading, in a non-selected cell array (non-selected block), V_{WL}, V_{SGS}, and V_{SGD} are grounded. That is, the word line WL, the SGS gate, and the SGD gate of the non-selected cell array are grounded during reading. In order to prevent a read error of the non-selected cell array, the thresholds Vt of the source line side select transistor and the bit line side select transistor must be higher than 0 V. As a result, the non-selected cell array may be completely in a disconnected state. Therefore, when a positive bias voltage is applied to the bit line BL and the source line and the P-well are grounded, in the case where the read cell of the selected block is a “1” cell, current flows from the bit line BL to the source line SL, and in the non-selected block, no current flows from the bit line BL to the source line SL.

In the NOR array, similar to the structure of the NAND array, the memory cell is connected between the source line side select transistor and the bit line side select transistor. Therefore, leakage current between the bit line and the source line of the non-selected block may be minimized through the source line side select transistor and the bit line side select transistor with relatively long gate lengths. Therefore, the gate length of the memory cell itself may be shortened, which may reduce the effective cell size to miniaturize the area of the memory cell.

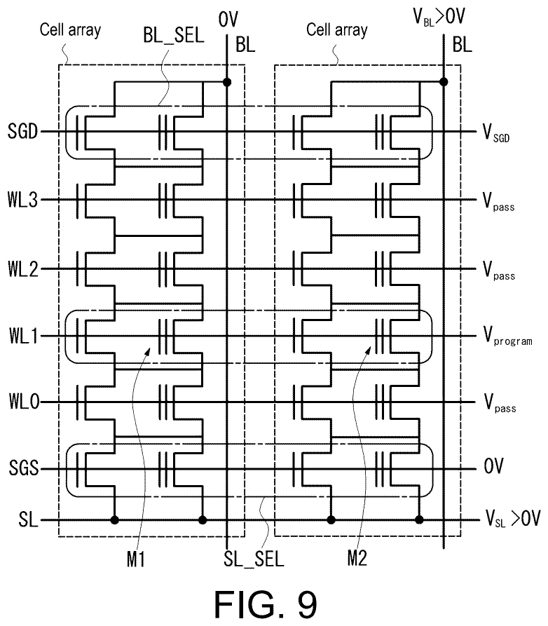

Table 2 shows the bias voltage during programming. During the program operation, a cell within a page may be programmed at a time. FIG. 9 shows two NOR cell arrays surrounded by dotted lines and shows an example in which “0” is programmed in a cell CM1 connected to the word line WL1 and “1” is programmed (that is, programming of “0” is prohibited) in a cell CM2.

TABLE 2
Program

| | Bias voltage | |
|---|---|---|
| V_{BL} (program “0”) | 0 | V |
| V_{BL} (program “1”) | 1.2~3 | V |
| V_{P-WELL} | 0 | V |
| V_{SL} | 1~2 | V |
| Selected block | | |
| V_{WL} (selected WL) | V_{program} = 8~16 V | |
| V_{WL} (non-selected WL) | Vₚₐₛₛ = V_{program}/2 | |
| V_{SGS} | 0 | V |
| V_{SGD} | 1~2 | V |
| Non-selected block | | |
| V_{WL} | 0 | V |
| V_{SGS} | 0 | V |
| V_{SGD} | 0 | V |

0 V is applied to the bit line BL of the cell array on the left, and a positive voltage (V_{BL}=1.2 V to 3 V) is applied to the bit line BL of the cell array on the right. A high voltage (V_{program}=8 V to 16 V) is applied to the selected word line WL to be programmed, and a voltage approximately half of V_{program} (Vₚₐₛₛ=4 V to 8 V) is applied to other word lines WL within the same cell array. A positive bias voltage (V_{SGD}=1 V to 2 V) is applied to the SGD gate, but must be higher than the threshold Vt of the bit line side select transistor BL_SEL. 0 V is applied to the SGS gate, a positive bias voltage (V_{SL}=1 V to 2 V) is applied to the source line SL, and the P-well is grounded.

Through applying 0 V to the bit line BL on the left and applying the positive bias voltage to the SGD gate, the bit line side select transistor BL_SEL is in a conducted state and the source side of the source line side select transistor SL_SEL is grounded. Through applying Vₚₐₛₛ to the non-selected cell, the non-selected cell is also in a conducted state, and 0 V is supplied to the channel region of the selected cell (the cell CM1 on the left connected to WL1). Through grounding the channel and applying the high voltage (V_{program}) to the word line WL1, electrons may be tunneled to the charge storage layer. Therefore, the threshold Vt of the cell CM1 increases, and the cell CM1 is programmed to a “0” state.

On the other hand, a positive bias voltage is applied to the bit line BL on the right, so the bit line side select transistor BL_SEL is in a disconnected state. Through applying 0 V to the SGS gate, the source line side select transistor SL_SEL is in a disconnected state. Therefore, the channel of the NOR cell array on the right is separated from the bit line BL and the source line SL. Afterwards, through applying Vₚₐₛₛ and V_{program} to the non-selected word line WL and the selected word line WL1, the channel region of the NOR cell array on the right may be increased. As a result, a voltage difference between the silicon surface and the word line WL is reduced, tunneling of electrons from the silicon surface to the charge storage layer disappears, and the threshold Vt of the cell CM2 does not shift. Therefore, the selected cell CM2 is programmed to “1”. The program sequence is basically the same as the programming of the conventional NAND flash memory.

In addition, during the program operation, V_{WL}, V_{SGS} and V_{SGD} of the non-selected blocks are grounded, and the non-selected blocks may be completely in a disconnected state through the source line side select transistor and the bit line side select transistor with relatively long gate lengths. Therefore, the gate length of the memory cell itself may be shortened, which may reduce the effective cell size.

Next, the erase operation will be described. Table 3 shows the bias voltage during the erase operation. In the NOR array, one block may be erased at a time. Through grounding all the word lines WL of the selected block and applying Vₑᵣₐₛₑ (8 V to 16 V) to the P-well, electrons within the charge storage layer move to the silicon surface or electron holes on the silicon surface tunnel into the charge storage layer. Thus, the threshold Vt of the cell shifts to a low value, and the cell is in a “1” state. The bit line BL, the source line SL, the SGS gate line, the SGD gate line, and the word line WL of the non-selected block are in a floating state. The word line WL is in a floating state, and V_{WL} is automatically increased to a magnitude close to V_{P-WELL}, so the threshold Vt of the cell in the non-selected block does not shift.

TABLE 3
Erase

| | Bias voltage |
|---|---|
| V_{BL} | Floating |
| V_{SL} | Floating |
| V_{P-WELL} | Vₑᵣₐₛₑ = 8~16 V |
| Selected block | |
| V_{WL} (selected WL) | 0 V |
| V_{SGS} | Floating |
| V_{SGD} | Floating |
| Non-selected block | |
| V_{WL} | Floating |
| V_{SGS} | Floating |
| V_{SGD} | Floating |

In addition, the thickness of the sidewall insulating film (thickness of oxide (Tox): effective oxide film thickness) serving as the gate insulating film of the sidewall transistor depends on V_{program} or Verase. In order to prevent insulation breakdown of the sidewall insulating film, an electric field applied between the second control gate and the sidewall of silicon (the active region) needs to be below 5 MV/cm (V_{program}/Tox≤5 MV/cm, and Vₑᵣₐₛₑ/Tox≤5 MV/cm).

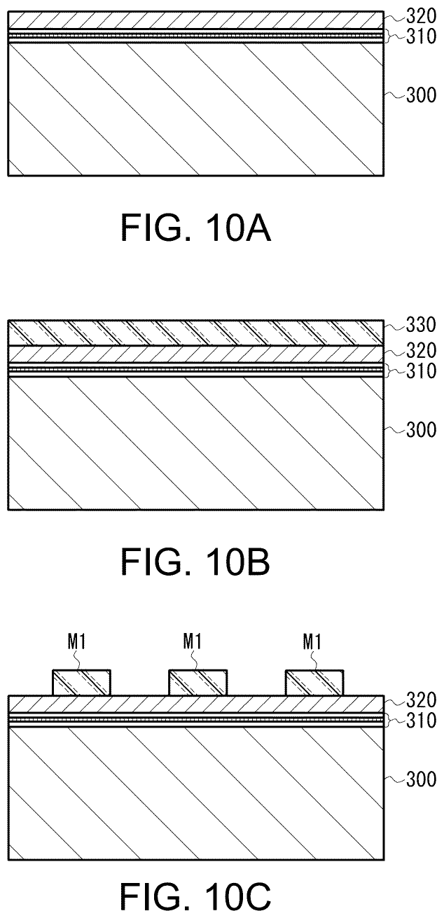

Next, a manufacturing process of the NAND array of the flash memory of the embodiment will be described with reference to FIG. 10A to FIG. 12B. As shown in FIG. 10A, on a surface of a P-type silicon substrate or Pe well 300 (hereinafter referred to as a substrate for convenience), an insulating film 310 having a three-layer structure of an oxide film such as SiO₂, a SiN film such as Si₃N₄, and an oxide film such as SiO₂ is formed through chemical vapor deposition (CVD), etc. In addition, in the following description, the insulating film 310 having the three-layer structure is referred to as a charge storage layer. In addition, a first control gate 320 made of, for example, polysilicon is formed on the charge storage layer 310.

Next, as shown in FIG. 10B, a mask material 330 such as a resist is, for example, formed. Next, the mask material 330 is patterned through a lithography process, as shown in FIG. 10C, to form mask patterns M1 spaced at specific intervals and extending along the bit line direction.

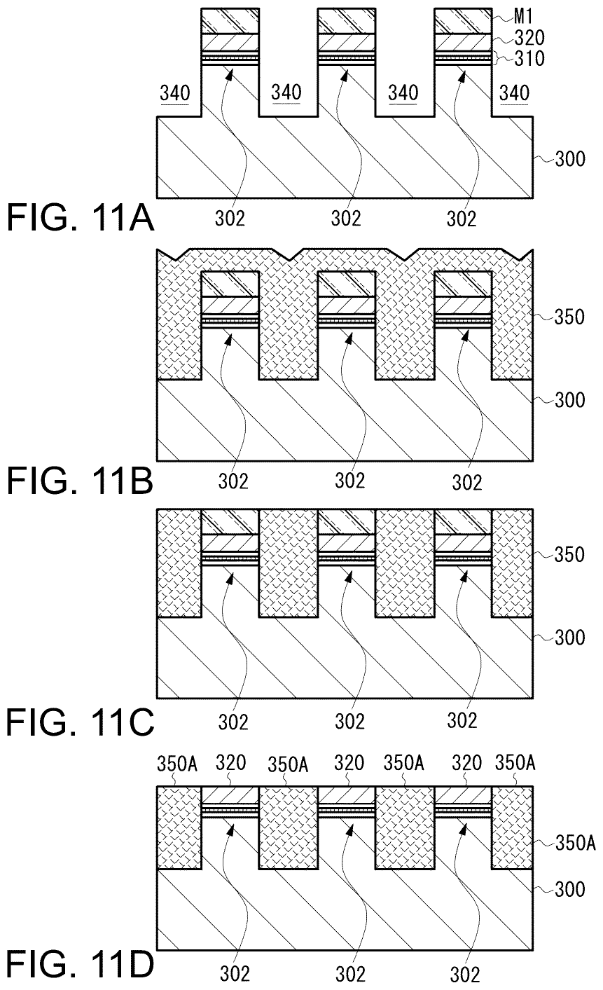

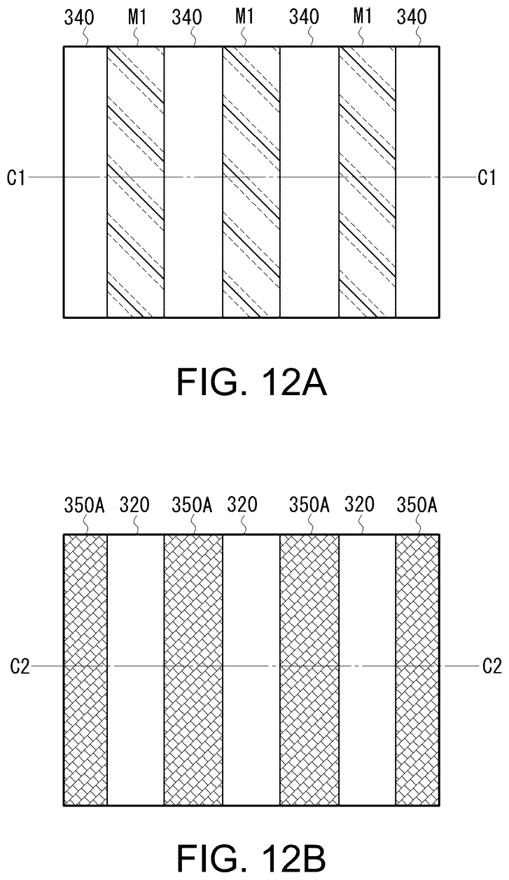

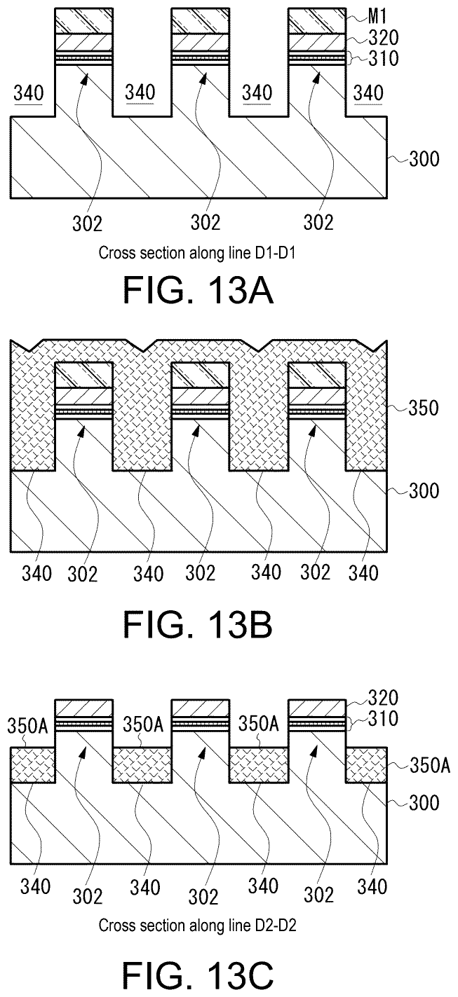

Next, as shown in FIG. 11A, the exposed first control gate 320, charge storage layer 310, and substrate 300 are simultaneously anisotropically etched through the mask patterns M1, and a stack of the patterned charge storage layer 310 and first control gate 320 is formed on the substrate 300, and a trench 340 for defining an active region 302 is simultaneously formed within the substrate 300. FIG. 13A is a plan diagram of a substrate when the first control gate 320, the charge storage layer 310, and the substrate 300 are etched through the mask patterns M1, and FIG. 11A corresponds to a cross section taken along a line C1-C1 of FIG. 12A.

The stack of the charge storage layer 310 and the first control gate 320 extends along the bit line direction, and the trench 340 is formed by self-aligning with a sidewall of the stack of the charge storage layer 310 and the first control gate 320. Therefore, the trench 340 is formed with high accuracy without positional error between the stack of the charge storage layer 310 and the first control gate 320. In addition, the charge storage layer 310 is covered by the first control gate 320 and is thus protected from being etched.

Next, as shown in FIG. 11B, an insulating film 350 is conformally formed on the substrate 300 including the trench 340. Then, the insulating film 350 is etched to near the surface of the substrate 300 to leave a trench insulator 350A within the trench 340. At this time, the mask patterns M1 protect the first control gate 320 from being etched.

Next, as shown in FIG. 11C, the trench insulator 350A is planarized by surface polishing to expose surfaces of the mask patterns M1. Next, as shown in FIG. 11D, the mask patterns M1 are removed, and a surface of the trench insulator 350A is polished, so that the height of the trench insulator 350A is substantially the same as the height of the first control gate 320. In this way, the active region 302 extending along the bit line direction is isolated by the trench insulator 350A, and the stack of the charge storage layer 310 and the first control gate 320 is formed in the active region 302. FIG. 12B is a plan diagram of a substrate when the heights of the first control gate 320 and the trench insulator 350A are substantially the same, and FIG. 11D corresponds to a cross section taken along a line C2-C2 of FIG. 12B. In addition, the manufacturing process shown in FIG. 11D may also be omitted.

Next, the manufacturing process of the NOR array of the flash memory of the embodiment will be described with reference to FIG. 13A to FIG. 15B. After the manufacturing process of FIG. 10A to FIG. 10C described above, as shown in FIG. 13A, the exposed first control gate 320, charge storage layer 310, and substrate 300 are simultaneously anisotropically etched through the mask patterns M1, and the stack of the charge storage layer 310 and the first control gate 320 patterned along the bit line direction is formed on the substrate 300. While patterning is being performed, the trench 340 defining the active region 302 is formed within the substrate 300. Next, as shown in FIG. 13B, the insulating film 350 is conformally formed on the substrate 300 including the trench 340. The manufacturing process up to this point is the same as the that of the NAND array.

Next, the insulating film 350 is etched to leave the trench insulator 350A within the trench 340. At this time, the mask patterns M1 protect the first control gate 320 from being etched.

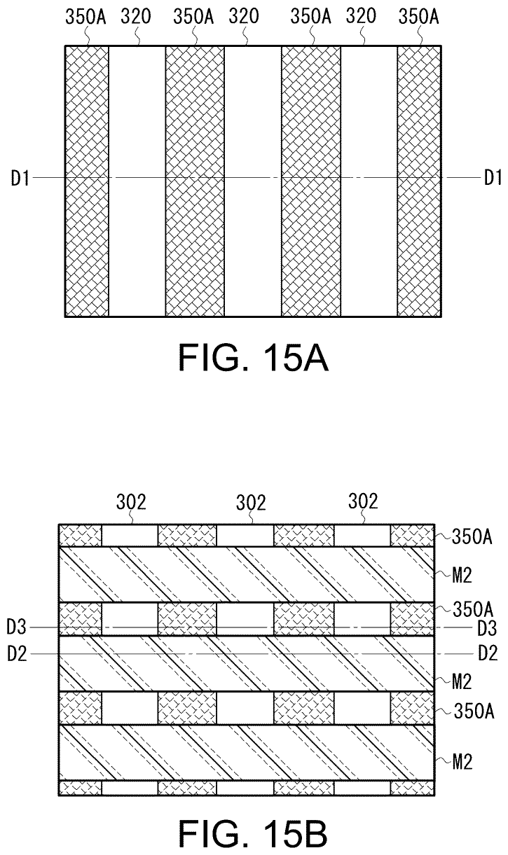

Next, as shown in FIG. 13C, the mask patterns M1 are removed. An outermost surface of the trench insulator 350A within the trench 340 is lower than an outermost surface of the active region 302. In this way, the active region 302 extending along the bit line direction is isolated by the trench insulator 350A, and the stack of the charge storage layer 310 and the first control gate 320 is formed in the active region 302. FIG. 15A is a plan diagram of a substrate after the mask patterns M1 are removed, and FIG. 13C corresponds to a cross section taken along a line D1-D1 of FIG. 15A.

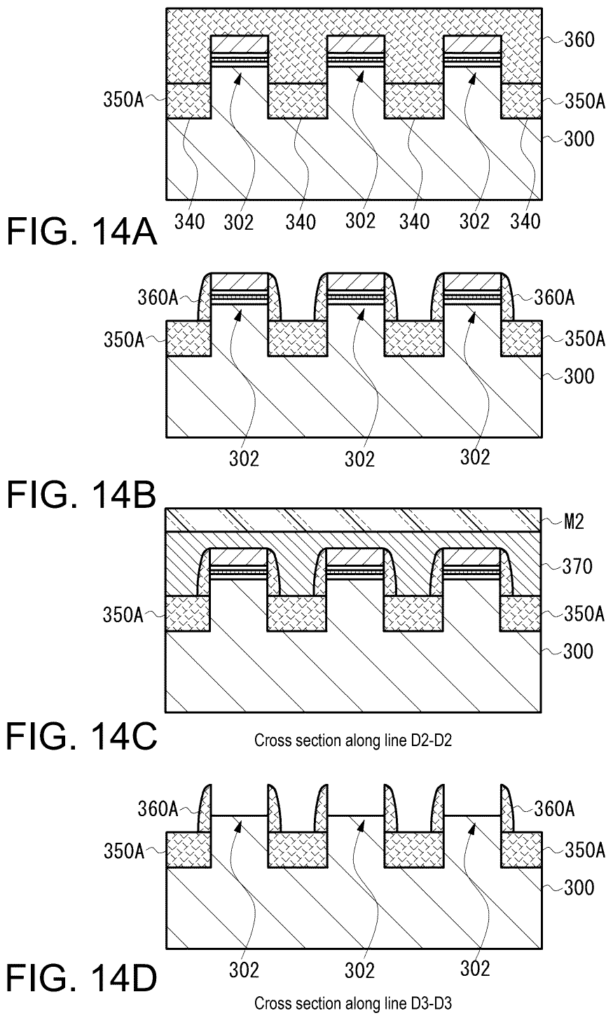

Next, as shown in FIG. 14A, an insulating film 360 is conformally formed on the substrate, and the insulating film 360 is anisotropically etched, so that as shown in FIG. 14B, a sidewall insulating film 360A covering sidewalls of the charge storage layer 310 and the first control gate 320 is formed. The sidewall insulating film 360A is connected to the trench insulator 350A at the bottom.

Next, as shown in FIG. 14C, a conductive material 370 is conformally formed on the substrate, and a mask pattern M2 extending along the word line direction is formed thereon. FIG. 15B is a plan diagram of a substrate after the mask pattern M2 is formed, and FIG. 14C corresponds to a cross section taken along a line D2-D2 of FIG. 15B. The conductive material 370 is etched through the mask pattern M2 to pattern the second control gate extending along the word line direction. At this time, in a region where the memory cell is not formed, as shown in FIG. 14D, the exposed conductive material 370, first control gate 320, and charge storage layer 310 are simultaneously etched through the mask pattern M2 to expose the active region 302. FIG. 14D corresponds to a cross section along a line D3-D3 of FIG. 15B.

Next, phosphorus or arsenic is ion-implanted into the exposed active region 302, and as shown in FIG. 6B, the N-type diffusion regions 280 and 280A are formed on the surface and the side surface of the active region 210. Next, an insulating film is conformally formed on the substrate including the second control gate, and the insulating film is planarized through chemical mechanical polishing (CMP), etc. until a surface of the second control gate is exposed.

In this way, the NOR array 110A and the NAND array 110B may be manufactured on the same substrate through a common manufacturing process or a compatible manufacturing process for manufacturing the stack of the charge storage layer 310 and the first control gate 320.

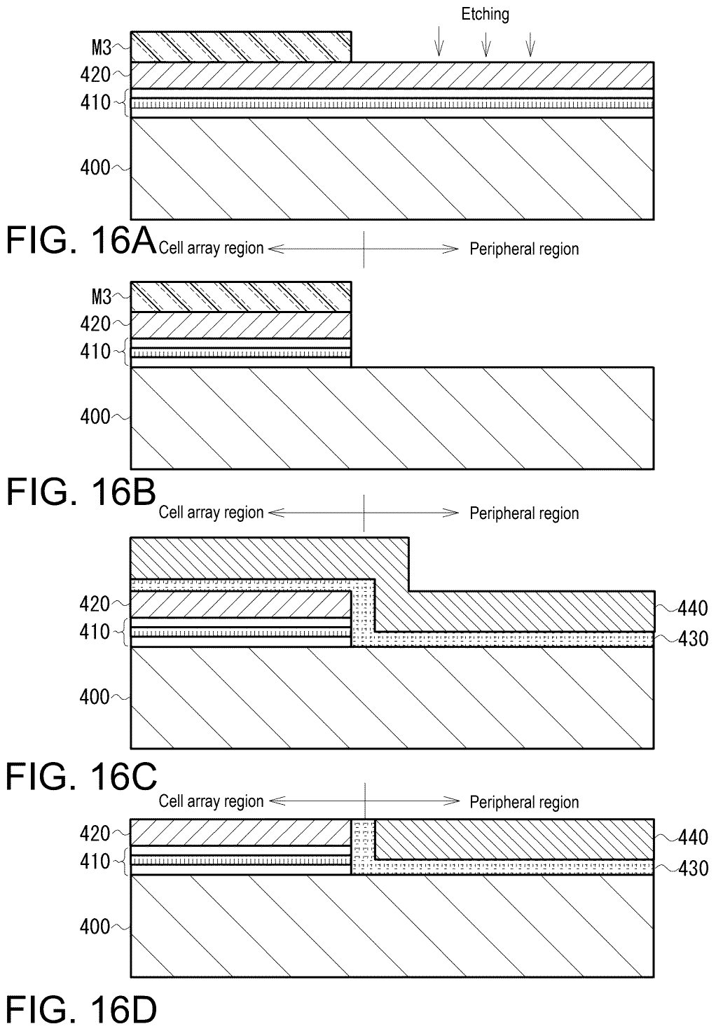

Next, a manufacturing process of a cell array region and a peripheral region in the flash memory of the embodiment will be described with reference to FIG. 16A to FIG. 19B. As shown in FIG. 16A, after a charge storage layer 410 and a first control gate (CG1) 420 are conformally formed on a P-type silicon substrate 400, a mask pattern M3 covering the cell array region is formed. Next, as shown in FIG. 16B, the charge storage layer 410 and the first control gate 420 in the peripheral region are removed through etching using the mask pattern M3 as an etch mask.

After removing the mask pattern M3, as shown in FIG. 16C, a gate insulating film 430 is conformally formed on the substrate 400 including the peripheral region. The gate insulating film 430 is, for example, a silicon oxide film. A sense amplifier, a decoder, etc. is formed in the peripheral region. The circuits include transistors driven by high voltage or transistors driven by low voltage. Therefore, the gate insulating film 430 is formed with various thicknesses, such as a thick film suitable for high voltage and a thin film suitable for low voltage. After the gate insulating film 430 is formed, a gate material 440 for the transistors in the peripheral region is conformally formed on the substrate 400. The gate material 440 is, for example, polysilicon.

Next, as shown in FIG. 16D, the gate insulating film 430 and the gate material 440 are etched back or planarized to expose the first control gate 420 in the cell array region and to expose the gate material 440 in the peripheral region. Via the manufacturing processes, the charge storage layer 410 and the first control gate 420 in the cell array region and the gate insulating film 430 and the gate material 440 in the peripheral region may be formed respectively.

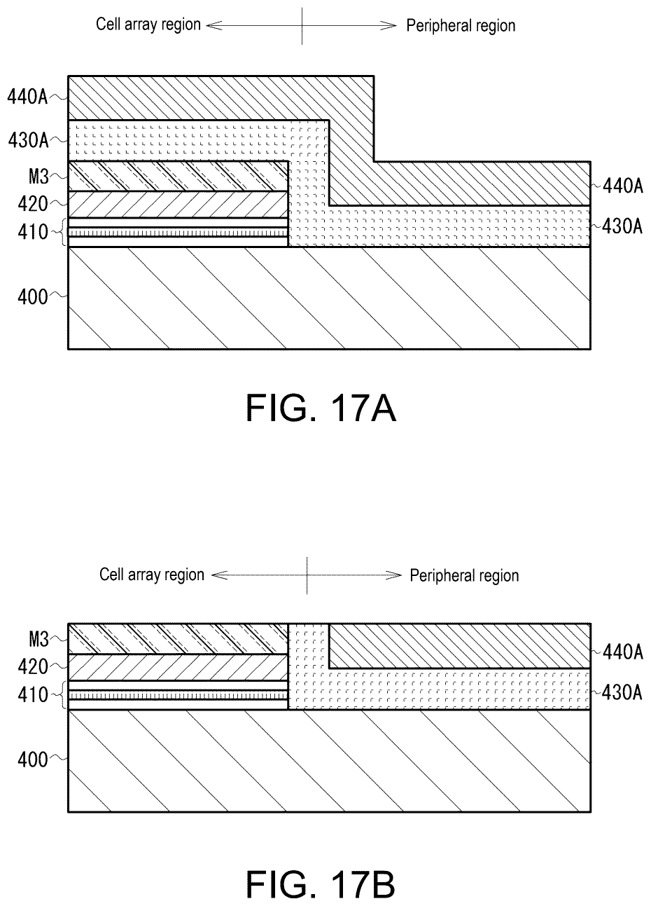

During the manufacturing process, after the mask pattern M3 is removed, the gate insulating film 430 and the gate material 440 are formed, but just as an example, the mask pattern M3 may also be retained. As shown in FIG. 17A, a gate insulating film 430A and a gate material 440A are conformally formed on a substrate including the mask pattern M3. In the case where the gate insulating film 430A in the peripheral region is a thick insulating film with high withstand voltage, the height of the mask pattern M3 in the cell array region is set to be substantially the same as the height of the gate material 440A. In addition, the gate insulating film 430A at a boundary between the cell array region and the peripheral region is set as a thick insulating film with high withstand voltage.

Next, as shown in FIG. 17B, planarization is performed to expose the mask pattern M3 in the cell array region and the gate material 440A in the peripheral region. Then, the mask pattern M3 is removed. Via the manufacturing processes, the charge storage layer 410 and the first control gate 420 in the cell array region and the gate insulating film 430A and the gate material 440A in the peripheral region may be formed separately.

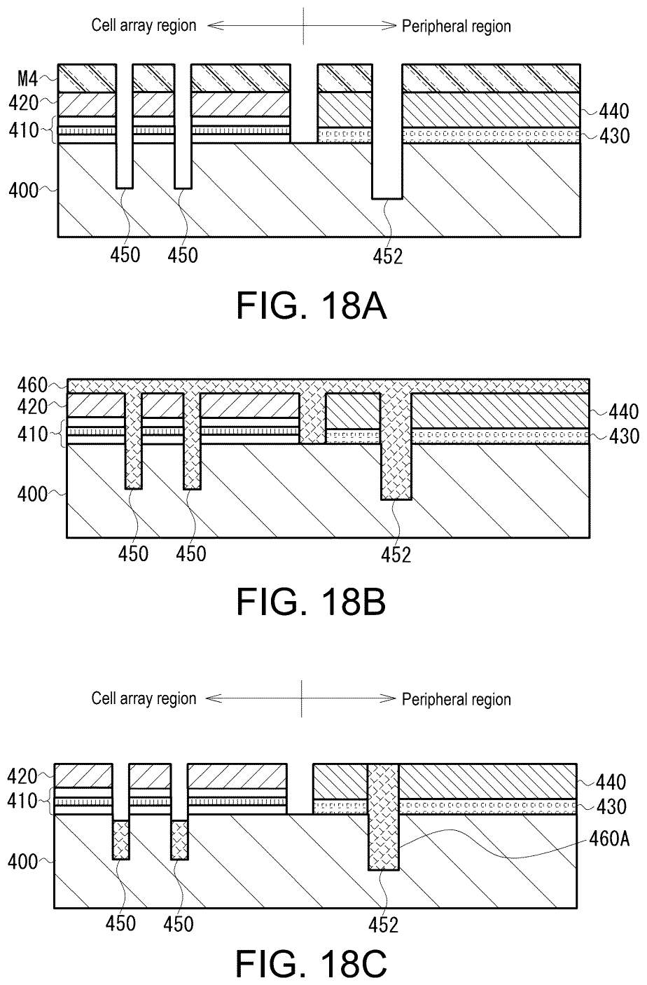

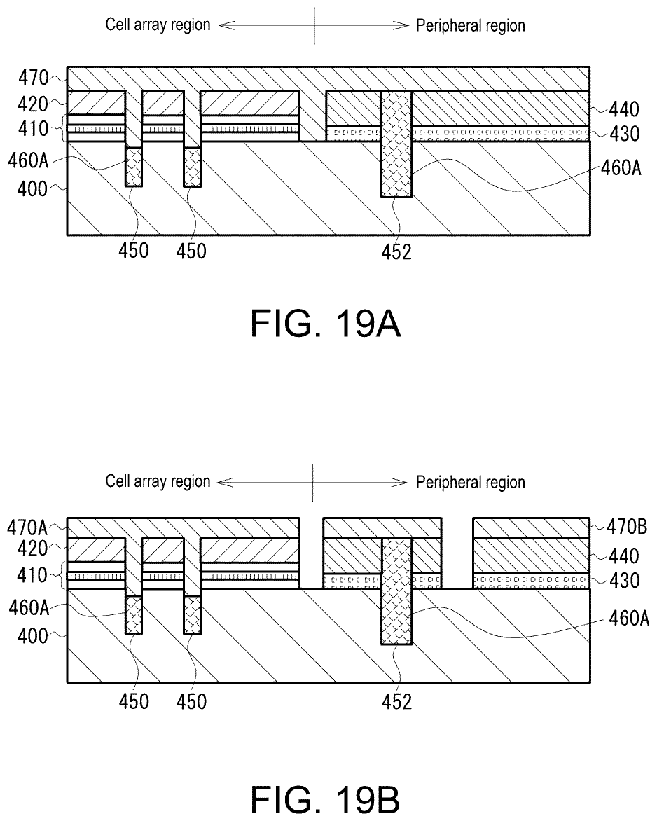

After respectively forming the first control gate 420 in the cell array region and the gate material 440 in the peripheral region, a mask pattern M4 as shown in FIG. 18A is formed. The gate materials, the gate insulating films, and silicon in the cell array region and the peripheral region are simultaneously etched to form a trench 450 and a trench 452 on the substrate 400. The trench 450 in the cell array region may have a different size and/or a different depth from the trench 452 in the peripheral region.

After removing the mask pattern M4, as shown in FIG. 18B, an insulating material 460 is filled into the trench 450 and the trench 452. The insulating material 460 is, for example, a silicon oxide film. Next, as shown in FIG. 18C, the insulating material 460 is etched to form a trench insulator 460A in the trench 450 and the trench 452. Furthermore, in the peripheral region, the trench insulator 460A filling the trench 452 is etched to the same height as the gate material 440 and is not etched to a deeper depth.

Next, as described above with reference to FIG. 14A and FIG. 14B, the sidewall insulating film is formed to cover the active region 302, the charge storage layer 310, and the sidewall of the first control gate 320 (not shown here).

Next, as shown in FIG. 19A, a conductive material 470 serving as a precursor of the second control gate is conformally formed on the substrate 400 including the first control gate 420 and the gate material 440. The conductive material 470 is not particularly limited and may be, for example, a metal material such as Al or Cu. The conductive material 470 is electrically connected to the first control gate 420 and the gate material 440. In addition, metal silicide may also be formed between the conductive material 470 and the first control gate 420 and the gate material 440.

As shown in FIG. 19B, through the mask pattern (not shown), the conductive material 470 in a region where the charge storage layer 410 and the first control gate 420 are formed within the cell array is patterned in a manner extending along the word line direction to form a second control gate 470A. The second control gate 470A is electrically connected to the corresponding first control gates 420 in the row direction and provides the word line. In addition, through the patterning of the conductive material 470, the first control gate 420 and the charge storage layer 410 located thereunder are simultaneously etched to expose the active region. On the other hand, through the patterning of the conductive material 470, a wiring layer 470B electrically connected to the gate material 440, etc. is formed in the peripheral region.

After the second control gate 470A is patterned, ion implantation is performed in the exposed active region to form an N-type doped region for the source/drain. Furthermore, similarly to the conventional NAND flash memory, the bit line BL and the source line SL are formed in the cell array region.

In this way, the flash memory of the embodiment includes the memory cell array 110 formed by integrating the NOR array 110A and the NAND array 110B on the silicon substrate, there is the charge storage layer formed by stacking multiple insulating layers including SiN between the silicon and the control gate, and the control gate is composed of two layers, that is, the first control gate formed on the charge storage layer and the second control gate formed on the first control gate. Through continuously depositing the charge storage layer and the first control gate on silicon, and simultaneously etching the first control gate, the charge storage layer, and silicon, a trench isolation region self-aligned with the first control gate and the charge storage layer may be formed. Afterwards, the second control gate is formed on the first control gate, and the first control gate and the second control gate are electrically connected to each other to form the word line. An end portion of the word line of the cell array region is connected to a row encoder, and the row encoder applies the bias voltage for the read/write (program)/erase operation to the word line WL.

Although the preferred embodiments of the disclosure have been described in detail, the disclosure is not limited to the specific embodiments, and various modifications and changes may be made within the scope of the disclosure described in the claims.

What is claimed is:

1. A semiconductor device, comprising a memory cell array formed by integrating a NOR memory cell array and a NAND memory cell array, wherein:
the memory cell array comprises:
an active region, formed by extending along a bit line direction within a substrate;
a trench, adjacent to the active region;
a charge storage layer, formed in the active region corresponding to each memory cell and comprising a nitride layer sandwiched between insulating layers;
a first conductive layer, formed on the charge storage layer corresponding to each memory cell; and
a second conductive layer, extending along a word line direction and electrically connected to the first conductive layer.

2. The semiconductor device according to claim 1, further comprising a bit line commonly connected to the NOR memory cell array and the NAND memory cell array.

3. The semiconductor device according to claim 1, further comprising a first bit line connected to the NOR memory cell array and a second bit line connected to the NAND memory cell array, wherein the first bit line and the second bit line are separated.

4. The semiconductor device according to claim 3, wherein the first bit line is connected to a first sense circuit, the second bit line is connected to a second sense circuit, the first sense circuit senses data of a selected memory cell of the NOR memory cell array, and the second sense circuit senses data of a selected memory cell of the NAND memory cell array.

5. The semiconductor device according to claim 1, wherein the first conductive layer and the second conductive layer form a word line.

6. The semiconductor device according to claim 1, wherein the NOR memory cell array further comprises a sidewall insulator, the sidewall insulator is formed within the trench and is formed on a sidewall of the active region,
the second conductive layer contacts the sidewall insulator within the trench.

7. The semiconductor device according to claim 6, wherein a NOR memory cell comprises a memory cell transistor formed on a surface side of the active region and a sidewall transistor comprising the sidewall insulator,
the memory cell transistor and the sidewall transistor are connected in parallel.

8. The semiconductor device according to claim 1, wherein the trench is aligned with sidewalls of the active region, the first conductive layer, and the charge storage layer.

9. The semiconductor device according to claim 1, wherein the charge storage layer comprises an oxide-nitride-oxide structure.

10. The semiconductor device according to claim 1, wherein a stacked structure of a plurality of insulating films other than oxide is comprised between a silicon substrate and a nitride layer.

11. The semiconductor device according to claim 1, wherein a stacked structure of a plurality of insulating films other than oxide is comprised between the nitride and the first conductive layer.

12. The semiconductor device according to claim 1, wherein the NOR memory cell array comprises a plurality of memory cells connected in series between a bit line side select transistor and a source line side select transistor.

13. The semiconductor device according to claim 1, wherein the NAND memory cell array comprises a plurality of memory cells connected in series between a bit line side select transistor and a source line side select transistor.

14. A semiconductor device, comprising:
a memory cell array, formed by integrating an NOR memory cell array and a NAND memory cell array;
a word line, connected to each memory cell; and
a bit line, connected to the NOR memory cell array and the NAND memory cell array, wherein
the NOR memory cell array comprises a plurality of memory cells connected in series between a bit line side select transistor and a source line side select transistor, and a memory cell comprises a memory cell transistor and a sidewall transistor connected in parallel,
the NAND memory cell array comprises a plurality of memory cells connected in series between a bit line side select transistor and a source line side select transistor.

15. The semiconductor device according to claim 14, wherein the bit line is commonly connected to the NOR memory cell array and the NAND memory cell array.

16. The semiconductor device according to claim 14, wherein the bit line comprises a first bit line connected to the NOR memory cell array and a second bit line connected to the NAND memory cell array, and the first bit line and the second bit line are separated.

17. The semiconductor device according to claim 16, wherein the first bit line is connected to a first sense circuit, the second bit line is connected to a second sense circuit, the first sense circuit senses data of a selected memory cell of the NOR memory cell array, and the second sense circuit senses data of a selected memory cell of the NAND memory cell array.

18. The semiconductor device according to claim 14, wherein a threshold of the sidewall transistor is set to be higher than a voltage of a selected word line and lower than a voltage of a non-selected word line.

19. The semiconductor device according to claim 14, further comprising a control unit for controlling reading and writing of the memory cell array, wherein
the control unit performs reading and writing of the NOR memory cell array in units of pages and in units of memory cells, and performs reading and writing of the NAND memory cell array in units of pages.
